(19) United States
(12) Patent Application Publication
(10) Pub. No.: US 2023/0369091 A1
(43) Pub. Date: Nov. 16, 2023

(54) HIGH TEMPERATURE PEDESTAL WITH EXTENDED ELECTROSTATIC CHUCK ELECTRODE

(71) Applicant: LAM RESEARCH CORPORATION, Fremont, CA (US)

(72) Inventors: Feng BI, Lake Oswego, OR (US); Yukinori SAKIYAMA, West Linn, OR (US); Niraj RANA, West Linn, OR (US); Pengyi ZHANG, Beaverton, OR (US); Simran SHAH, Portland, OR (US); Timothy Scott THOMAS, Wilsonville, OR (US); David FRENCH, Fort Myers, FL (US); Vincent BURKHART, Cupertino, CA (US)

(21) Appl. No.: 18/028,689

(22) PCT Filed: Sep. 28, 2021
(86) PCT No.: PCT/US2021/052451

§ 371 Date: Mar. 27, 2023

Related U.S. Application Data
(60) Provisional application No. 63/086,561, filed on Oct. 1, 2020.

(51) Int. Cl. H01L 21/683; H01J 37/32; C23C 16/458

(52) U.S. Cl. CPC H01L 21/6833; H01J 37/32724; C23C 16/4586; C23C 16/4585

(57) ABSTRACT

A substrate support configured to support a substrate having a diameter D comprises a first inner electrode and a second inner electrode that are each D-shaped, define a first outer diameter that is less than D, and are configured to be connected to an electrostatic chuck voltage to clamp the substrate to the substrate support. An outer electrode comprises a ring-shaped outer portion that surrounds the first inner electrode and the second inner electrode and a center portion that pass between the first inner electrode and the second inner electrode to connect to opposite sides of an inner diameter of the ring-shaped outer portion. The inner diameter of the ring-shaped outer portion is greater than the diameter D such that the inner diameter of the ring-shaped outer portion and intersections between the center portion and the ring-shaped outer portion are located radially outside of the diameter D of the substrate.

### CROSS-REFERENCE TO RELATED APPLICATIONS

This application claims the benefit of U.S. Provisional Application No. 63/086,561, filed on Oct. 1, 2020. The entire disclosure of the application referenced above is incorporated herein by reference.

### FIELD

The present disclosure relates to substrate support pedestals in substrate processing systems.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems may be used to treat substrates such as semiconductor wafers. Examples of substrate treatments comprise etching, deposition, photoresist removal, etc. During processing, the substrate is arranged on a substrate support such as an electrostatic chuck and one or more process gases may be introduced into the processing chamber.

The one or more process gases may be delivered by a gas delivery system to the processing chamber. In some systems, the gas delivery system comprises a manifold connected by one or more conduits to a showerhead that is located in the processing chamber. In some examples, deposition processes such as chemical vapor deposition (CVD), plasma enhanced CVD (PECVD), atomic layer deposition (ALD), etc. are used to deposit material on a substrate.

### SUMMARY

A substrate support configured to support a substrate having a diameter D comprises a first inner electrode and a second inner electrode that are each D-shaped and define a first outer diameter that is less than D and are configured to be connected to an electrostatic chuck (ESC) voltage to clamp the substrate to the substrate support during processing. An outer electrode comprises a ring-shaped outer portion that surrounds the first inner electrode and the second inner electrode and a center portion that pass between the first inner electrode and the second inner electrode to connect to opposite sides of an inner diameter of the ring-shaped outer portion. The inner diameter of the ring-shaped outer portion is greater than the diameter D such that the inner diameter of the ring-shaped outer portion and intersections between the center portion and the ring-shaped outer portion are located radially outside of the diameter D of the substrate.

In other features, the substrate support further comprises a gap defined between the first outer diameter defined by the first inner electrode and the second inner electrode and the inner diameter of the ring-shaped outer portion. The gap is located below and overlaps with an outer edge of the substrate. The gap has a width between 2.2 and 7.5 mm. The inner diameter of the ring-shaped outer portion is less than 1.0 mm greater than the diameter D of the substrate. The inner diameter of the ring-shaped outer portion is between 300.4 and 305 mm. The first outer diameter defined by the first inner electrode and the second inner electrode is between 290 and 296 mm.

In other features, the substrate support further comprises a pocket in a first surface of the substrate support. The pocket is configured to hold the substrate. The substrate support further comprises the substrate arranged in the pocket. A diameter of the pocket is between 302 and 310 mm. The inner diameter of the ring-shaped outer portion overlaps the pocket.

A method of depositing a hard mask film on a substrate having a diameter D comprises arranging the substrate on a substrate support in a processing chamber. The substrate support comprises a first inner electrode and a second inner electrode that are each D-shaped and define a first outer diameter that is less than D and an outer electrode that comprises a ring-shaped outer portion that surrounds the first inner electrode and the second inner electrode and a center portion that passes between the first inner electrode and the second inner electrode to connect to opposite sides of an inner diameter of the ring-shaped outer portion. The inner diameter of the ring-shaped outer portion is greater than the diameter D such that the inner diameter of the ring-shaped outer portion and intersections between the center portion and the ring-shaped outer portion are located radially outside of the diameter D of the substrate. The method further comprises connecting the first inner electrode and the second inner electrode to an electrostatic chuck (ESC) voltage to clamp the substrate to the substrate support and depositing the hard mask film onto the substrate. Depositing the hard mask film comprises generating plasma within the processing chamber.

In other features, the method further comprises defining a gap between the first outer diameter defined by the first inner electrode and the second inner electrode and the inner diameter of the ring-shaped outer portion. The gap is located below and overlaps with an outer edge of the substrate. The gap has a width between 2.2 and 7.5 mm. The inner diameter of the ring-shaped outer portion is less than 1.0 mm greater than the diameter D of the substrate. The inner diameter of the ring-shaped outer portion is between 300.4 and 305 mm. The first outer diameter defined by the first inner electrode and the second inner electrode is between 290 and 296 mm.

In other features, the method further comprises arranging the substrate in a pocket in a first surface of the substrate support. A diameter of the pocket is between 302 and 310 mm. The inner diameter of the ring-shaped outer portion overlaps the pocket.

A substrate support configured to support a substrate comprises a first inner electrode and a second inner electrode that are each D-shaped and are configured to be connected to an electrostatic chuck (ESC) voltage to clamp the substrate to the substrate support during processing. An outer electrode comprises a ring-shaped outer portion that surrounds the first inner electrode and the second inner electrode and a center portion that connects to opposite sides of an inner diameter of the ring-shaped outer portion. The outer electrode is not coplanar with the first inner electrode and the second inner electrode.

In other features, the outer electrode is positioned below the first inner electrode and the second inner electrode. The center portion comprises a plurality of radial conductors that extend outward from a conductive rod to connect to the ring-shaped outer portion. The plurality of radial conductors comprises two or more of the radial conductors. The plurality of radial conductors comprises four or more of the radial conductors.

A substrate support configured to support a substrate comprises a first inner electrode and a second inner electrode. The first inner electrode and the second inner electrode are each D-shaped. The first inner electrode and the second inner electrode are configured to be connected to an electrostatic chuck (ESC) voltage to clamp the substrate to the substrate support during processing. An outer electrode comprises a ring-shaped outer portion that surrounds the first inner electrode and the second inner electrode, a center portion positioned below the ring-shaped outer portion, a ring electrically connected to the center portion that surrounds and is coplanar with the center portion, and at least one vertical portion that electrically connects the ring to the ring-shaped outer portion.

In other features, the center portion comprises a plurality of radial conductors that extend outward from a conductive rod to connect to the ring. The plurality of radial conductors comprises two or more of the radial conductors. The plurality of radial conductors comprises four or more of the radial conductors.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system according to the present disclosure;

FIG. 2A is a substrate support comprising an example electrostatic chuck (ESC) electrode according to the present disclosure;

FIG. 2B is a plan view of the ESC electrode of FIG. 2A;

FIG. 3 is an isometric view of an example ring-shaped outer electrode according to the present disclosure;

FIG. 4 illustrates steps of an example method for performing a deposition process using a substrate support according to the present disclosure

FIG. 5A is a substrate support comprising another example ESC electrode according to the present disclosure;

FIG. 5B is a plan view of the ESC electrode of FIG. 5A;

FIG. 5C is a substrate support comprising another example ESC electrode according to the present disclosure;

FIG. 5D is a plan view of another ESC electrode according to the present disclosure;

FIG. 5E is a plan view of another example arrangement of the ESC electrode of FIG. 5D;

FIG. 5F is an isometric view of the example ring-shaped outer electrode of FIGS. 5D and 5E;

FIG. 6A is a substrate support comprising another example ESC electrode according to the present disclosure;

FIG. 6B is an isometric view of the example ring-shaped outer electrode of FIG. 6A.

In the drawings, reference numbers may be reused to identify similar and/or identical elements.

### DETAILED DESCRIPTION

In film deposition processes such as chemical vapor deposition (CVD), plasma enhanced CVD (PECVD), atomic layer deposition (ALD), etc., various properties of the deposited film vary across a spatial (i.e., x-y coordinates of a horizontal plane) and azimuthal distribution. For example, substrate processing tools may have respective specifications for film thickness non-uniformity (NU). Film thickness NU may be measured as a full-range, a half-range, and/or a standard deviation of a measurement set taken at predetermined locations on a surface of a semiconductor substrate.

Some example processes having high aspect ratio features may have greater sensitivity to film thickness NU. For example, in 3D NAND memory fabrication, a hard mask film (e.g., a high temperature, ashable hard mask) may be deposited to pattern channel holes in slits between stacks of alternating films. Accurate etching of the high aspect ratio channel holes may require the hard mask film to be ultra-flat (i.e., within a substrate half range thickness NU percentage of ≤7%).

In some examples, NUs may be reduced either by addressing a direct cause of the NU. NUs may also be reduced by introducing a counteracting NU to compensate and cancel the existing NU. In other examples, material may be intentionally deposited and/or removed non-uniformly to compensate for known non-uniformities at other (e.g. previous or subsequent) steps in a process.

Deposition rates may be partially dependent upon substrate and substrate support temperatures. Accordingly, temperature NUs (i.e., differences in temperatures across the substrate) may cause different deposition rates and corresponding film thickness NUs. A substrate processing system may implement various temperature control schemes to control the temperatures of the substrate to minimize NUs. For example, a substrate support may comprise a heater layer. The heater layer may comprise one or more zones that are respectively controlled to maintain desired temperatures of the substrate support and, correspondingly, the substrate.

In other examples, other features of the substrate support may introduce and/or increase film deposition NUs. For example, one or more electrostatic chuck (ESC) electrodes are arranged in a substrate support configured as an ESC. A voltage is supplied to the electrodes to clamp the substrate to the substrate support. The substrate support may comprise two or more electrodes (e.g., one or more inner clamping electrodes surrounded by an outer guard electrode). Geometry of the electrodes may cause an increase in plasma density (e.g., plasma “hotspots”) above certain portions of the substrate. For example, the outer electrode may comprise a ring-shaped portion (a guard ring or electrode) and a center portion (e.g., one or more radial conductors, such as a center strip or band) bisecting the ring portion. Plasma hotspots may occur above intersections of the ring-shaped portion and the center portion. The local plasma hotspots cause non-uniform plasma distribution and, correspondingly, high azimuthal film deposition NUs.

An ESC electrode arrangement according to the present disclosure eliminates plasma hotspots above the substrate caused by electrode geometry. For example, the ESC electrode arrangement comprises two D-shaped inner electrodes and an outer electrode comprising a ring-shaped portion. The inner and outer electrodes may comprise molybdenum. A center portion (e.g., a center strip) passes through a gap between the D-shaped inner electrodes to connect to opposite sides of an inner diameter of the ring-shaped portion. For example, the center portion corresponds to two co-linear radial conductors extending outward to connect to the outer electrode. Intersections (i.e., connection points or nodes) between the ring-shaped portion and the center portion are located radially outside of the substrate. For example, an inner diameter of the ring-shaped portion is greater than an outer diameter of the substrate. Accordingly, plasma hotspots caused by the intersections between the ring-shaped portion and the center portion are not formed above the substrate and do not affect film deposition rates. A such, azimuthal deposition uniformity is improved.

Further, an ESC voltage may be applied to the D-shaped inner electrodes while the ESC voltage is not applied to the outer electrode. If the outer electrode is below the outer edge of the substrate, chucking force will not be applied to the edge of the substrate. Accordingly, the increasing a diameter or perimeter defined by the D-shaped electrodes relative to the diameter of the substrate extends the chucking force to the edge of substrate and the pedestal can accommodate a highly bowed substrate.

In another example, the outer electrode is arranged in a different plane than (i.e., is not coplanar with) the D-shaped inner electrodes. For example, the outer electrode is arranged below the inner electrodes. The radial conductors of the center portion may have a width that is less than, the same as, or greater than a width of the gap between the D-shaped inner electrodes. The radial conductors may be aligned (i.e., coaxial) with or not aligned with the gap between the D-shaped inner electrodes. The ring-shaped portion and the center portion may be formed in a single step (e.g., a single sintering step). In this manner, intersections between the center portion and the ring-shaped portion are shifted below the inner electrodes in a direction away from the first surface of the substrate. According, occurrence of plasma hotspots above the substrate are reduced or eliminated. Further, an impedance of the outer electrode may be adjusted by locating the outer electrode at different heights relative to the first surface of the substrate support and the inner electrodes.

Further, the center portion may comprise more than two radial conductors (e.g., three, four, or more radial conductors) extending radially outward from a center point (e.g., corresponding to a location of a conductive rod) toward the ring-shaped portion. In this manner, the electrical connection to the ring-shaped portion is distributed among a greater number (i.e., quantity) of radial conductors. This reduces both the impedance of the ring-shaped portion and localized heating caused by individual ones of the radial conductors.

In another example, the ring-shaped portion is arranged in a same plane as (i.e., is coplanar with) or a different plane than (i.e., is not coplanar with) the D-shaped inner electrodes. The center portion is arranged in a plane below (i.e., is not coplanar with) the ring-shaped portion and the D-shaped inner electrodes. For example, the center portion is arranged below the ring-shaped portion and the inner electrodes. The radial conductors of the center portion may have a width that is less than, the same as, or greater than a width of the gap between the D-shaped inner electrodes. The radial conductors may be aligned (i.e., coaxial) with or not aligned with the gap between the D-shaped inner electrodes. The center portion may comprise two, three, four, or more of the radial conductors. The radial conductors are electrically connected to the ring-shaped portion via respective vertical portions.

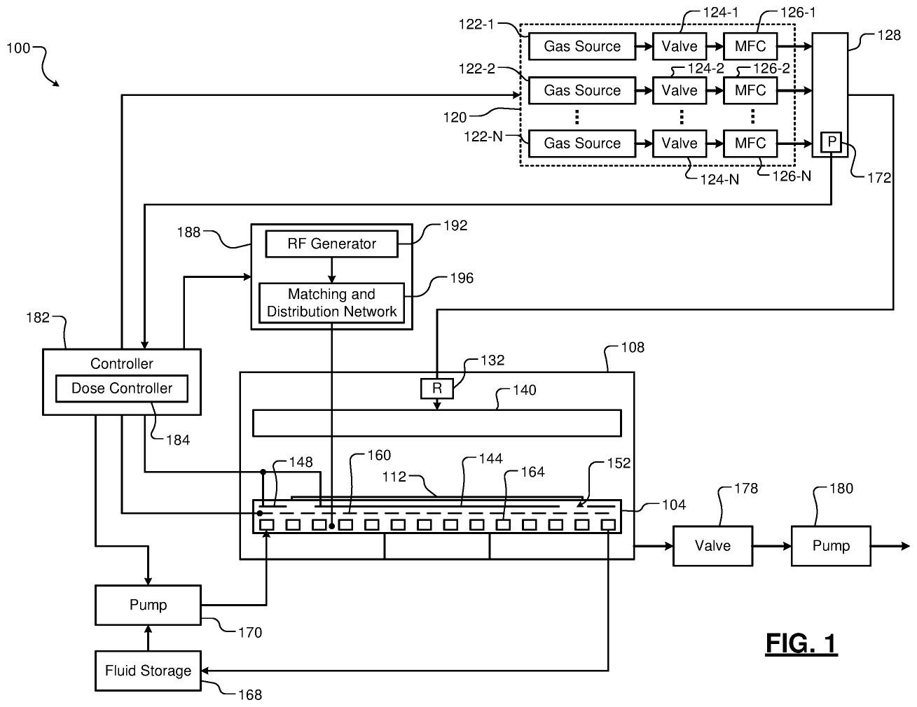

Referring now to FIG. 1, an example of a substrate processing system 100 comprising a substrate support (e.g., a pedestal) 104 according to the present disclosure is shown. The substrate support 104 is arranged within a processing chamber 108. A substrate 112 is arranged on the substrate support 104 during processing.

A gas delivery system 120 comprises gas sources 122-1, 122-2, . . . , and 122-N (collectively gas sources 122) that are connected to valves 124-1, 124-2, . . . , and 124-N (collectively valves 124) and mass flow controllers 126-1, 126-2, . . . , and 126-N (collectively MFCs 126). The MFCs 126 control flow of gases from the gas sources 122 to a manifold 128 where the gases mix. An output of the manifold 128 is supplied via an optional pressure regulator 132 to a gas distribution device such as a multi-injector showerhead 140.

The substrate support 104 according to the present disclosure is configured to function as an ESC. For example, the substrate support 104 comprises one or more ESC electrodes, such as one or more inner (e.g., D-shaped) electrodes 144 and an outer (e.g., ring-shaped) electrode 148. The inner electrodes 144 and the outer electrode 148 are configured such that a gap 152 between the inner electrodes 144 and the outer electrode 148 is located below (i.e., overlaps with) an outer edge of the substrate 112 as described below in more detail. For example, an inner diameter of the outer electrode 148 is greater than an outer diameter of the substrate 112. Further, an intersection/connection node between the outer electrode 148 and a center portion (not shown in FIG. 1) is located radially outside of the outer diameter of the substrate 112.

In some examples, a temperature of the substrate support 104 may be controlled using a heater layer, such as resistive heaters 160. The substrate support 104 may comprise coolant channels 164. Cooling fluid is supplied to the coolant channels 164 from a fluid storage 168 and a pump 170. A pressure sensor 172 may be arranged in the manifold 128 to measure pressure. A valve 178 and a pump 180 may be used to evacuate reactants from the processing chamber 108 and/or to control pressure within the processing chamber 108.

A controller 182 comprises a dose controller 184 that controls dosing provided by the multi-injector showerhead 140. The controller 182 also controls gas delivery from the gas delivery system 120. The controller 182 controls pressure in the processing chamber and/or evacuation of reactants using the valve 178 and the pump 180. The controller 182 controls the temperature of the substrate support 104 and the substrate 112 based upon temperature feedback (e.g., from sensors (not shown) in the substrate support and/or sensors (not shown) measuring coolant temperature). The controller 182 controls selectively supplying power to the inner electrodes 144 to clamp the substrate 112 to the substrate support 104. The outer electrode 148 may be connected to a reference potential, such as ground.

In some examples, the substrate processing system 100 may be configured to perform etching on the substrate 112 within the same processing chamber 108. Accordingly, the substrate processing system 100 may comprise an RF generating system 188 configured to generate and provide RF power (e.g., as a voltage source, current source, etc.) to a first electrode (e.g., a baseplate of the substrate support 104, as shown) and second electrode (e.g., the showerhead 140). For example purposes only, the output of the RF generating system 188 will be described herein as an RF voltage.

The first electrode and the second electrode may be DC grounded, AC grounded or floating. For example, the RF generating system 188 may comprise an RF generator 192 configured to generate the RF voltage that is fed by a matching and distribution network 196 to generate plasma within the processing chamber 108 to etch the substrate 112. In other examples, the plasma may be generated inductively or remotely. Although, as shown for example purposes, the RF generating system 188 corresponds to a capacitively coupled plasma (CCP) system, the principles of the present disclosure may also be implemented in other suitable systems, such as, for example only transformer coupled plasma (TCP) systems, CCP cathode systems, remote microwave plasma generation and delivery systems, etc.

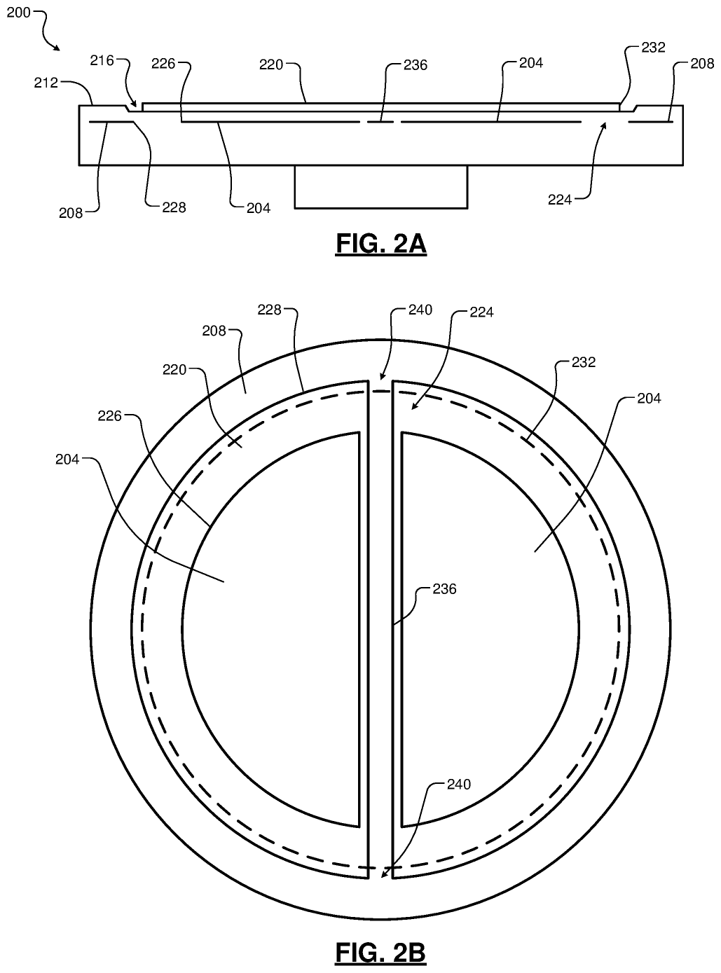

Referring now to FIGS. 2A and 2B, an example substrate support 200 according to the present disclosure comprises two D-shaped (e.g., first and second) inner electrodes 204 and a ring-shaped outer electrode 208. For example, the inner electrodes 204 correspond to ESC clamping electrodes. The outer electrode 208 corresponds to an ESC guard electrode. The inner electrodes 204 are respectively connected to ESC voltages (e.g., responsive to the controller 182) having opposite polarities to generate a clamping voltage across the substrate support 200. Conversely, the outer electrode 208 is connected to a reference potential (e.g., ground) to function as a guard ring. In various examples, the ESC voltages can be pulsed or continuous wave voltages, RF or DC voltages, same or different for each of the electrodes 204, provided by same or different sources, have same or different frequencies, etc.

A first (e.g., upper) surface 212 of the substrate support 200 comprises a pocket 216 configured to hold a substrate 220 arranged on the substrate support 200. A gap 224 is defined between the inner electrodes 204 (e.g., an outer diameter 226 defined by outer semi-circular edges of the inner electrodes 204) and an inner edge or diameter 228 of the outer electrode 208.

The gap 224 is located below an outer edge or diameter 232 of the substrate 220. Further, the inner diameter 228 of the outer electrode 208 is located radially outside of the outer diameter 232 of the substrate 220. In other words, the inner diameter 228 of the outer electrode 208 is greater than the outer diameter 232 of the substrate. For example, the substrate 220 may be a standard size (i.e., a diameter D), such as 300 mm. The pocket 216 may have a diameter greater than 300 mm to accommodate the substrate 220 (e.g., between 302 and 310 mm). The inner diameter 228 of the outer electrode 208 may be between 300.4 and 305 mm. The outer diameter 226 of the inner electrodes 204 may be between 290 and 296 mm. As shown, the inner diameter 228 of the outer electrode 208 overlaps the pocket 216. In other examples, the inner diameter 228 of the outer electrode 208 is located radially outside of (i.e., does not overlap) the pocket 216. The gap 224 may have a width between 2.2 and 7.5 mm.

The inner diameter 228 of the outer electrode 208 may be only slightly (e.g., less than 1.0 mm, or between 0.2 and 1.0 mm) greater than the outer diameter 232 of the substrate 220. For example, if the inner diameter 228 of the outer electrode 208 is too large (i.e., too much greater than the outer diameter 232 of the substrate 220), a DC electric field may leak from the substrate support 200 to RF plasma formed above the substrate 220, which may alter RF plasma behavior. In other words, if the inner diameter 228 is too large, the outer electrode 208 will not sufficiently suppress DC electric field leakage and will therefore not properly function as a guard electrode. Conversely, if the outer diameter 226 of the inner electrodes 204 is too small, the edge of the substrate 220 is not clamped to the substrate support 104 because an ESC voltage applied to the inner electrodes 204 does not extend to the outer diameter 232 of the substrate 220. Accordingly, the inner diameter 228 of the outer electrode 208 and the outer diameter 226 of the inner electrodes 204 are selected to optimize suppression of DC electric field leakage while still preventing plasma hotspots above the outer diameter 232 of the substrate 220. Further, since the inner diameter 228 is increased, the outer diameter 226 of the inner electrodes 204 is correspondingly increased to maximize the clamping force to the edge of substrate 220 to the substrate support 104.

A center strip or portion 236 (e.g., comprising two radial conductors) passes between the inner electrodes 204 to connect to opposite sides of the ring-shaped outer electrode 208. For example, the center portion 236 bisects a central opening of the outer electrode 208 to define two D-shaped openings. The inner electrodes 204 are arranged within the respective D-shaped openings. Plasma hotspots (i.e., regions of increased plasma density) may occur above intersections (e.g., as indicated at 240) between the center portion 236 and the outer electrode 208. Accordingly, the intersections 240 are located radially outside of the outer diameter 232 of the substrate 220. In other words, since the inner diameter 228 of the outer electrode 208 is located radially outside of the outer diameter 232 of the substrate 220, the intersections 240 where the center portion 236 meets the inner diameter 228 of the outer electrode 208 are also located radially outside of the outer diameter 232 of the substrate 220.

In this manner, any plasma hotspots caused by the intersections 240 between the center portion 236 and the outer electrode 208 occur radially outside of the outer diameter 232 of the substrate 220. Accordingly, the plasma hotspots do not cause film deposition NUs on the substrate 220.

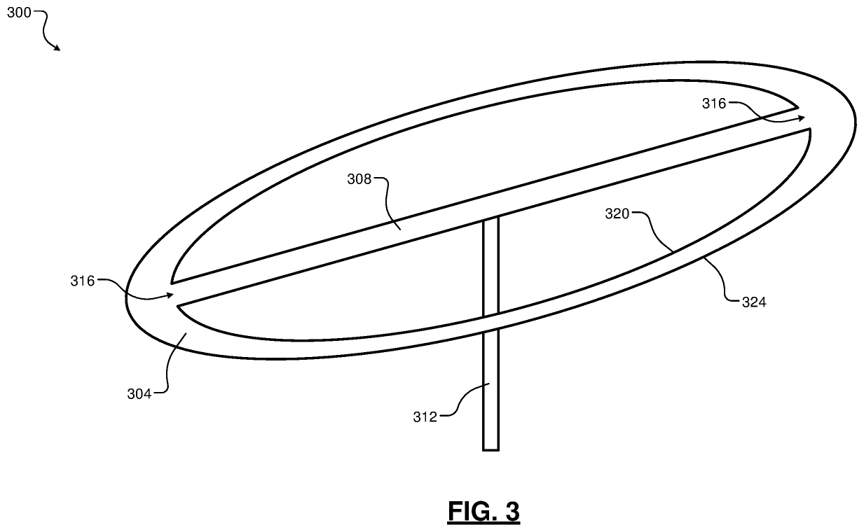

Referring now to FIG. 3, an example ring-shaped outer electrode 300 according to the present disclosure is shown. The outer electrode 300 comprises an annular outer portion 304 and a center strip or portion 308. The center portion 308 (and, correspondingly, the outer portion 304) is a radial conductor connected to a reference voltage or potential (e.g., ground) via a conductive wiring or a conductive rod 312. In this manner, the center portion 308 electrically connects the annular outer portion 308 to the conductive rod 312.

The center portion 308 functions as an inductive element. Further, the center portion 308 may be capacitively coupled to plasma formed above the substrate during plasma processing. Accordingly, a high voltage region may be formed at intersections 316 between the center portion 308 and the outer portion 304. Increasing an inner diameter 320 of the outer portion 304 (and, correspondingly, increasing a length of the center portion 308 and radial locations of the intersections 316) such that the inner diameter 320 is greater than an outer diameter of the substrate moves the intersections 316 and corresponding plasma hotspots radially outside of the outer diameter of the substrate as described above in FIGS. 2A and 2B.

While the inner diameter 320 of the outer portion 304 is increased, an outer diameter 324 may not be increased. Accordingly, a cross-sectional width of the outer portion 304 may be decreased relative to other ring-shaped guard electrodes that overlap with the substrate. For example only, the cross-sectional width of the outer portion 304 is between 15 and 20 mm.

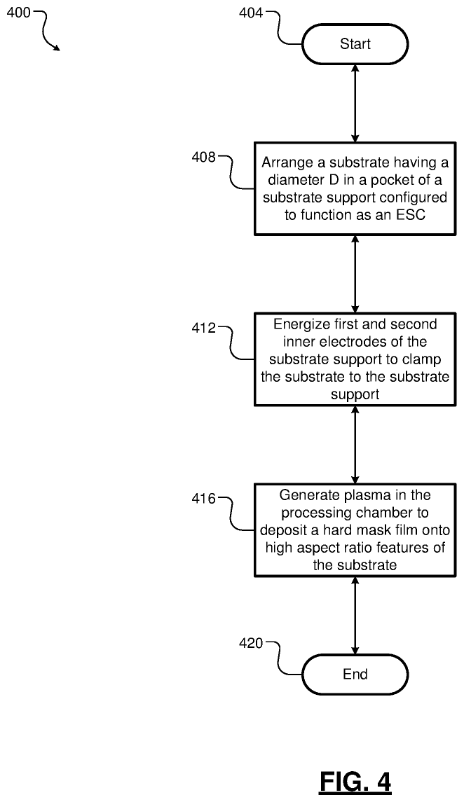

Referring now to FIG. 4, an example method 400 for performing a deposition process using a substrate support according to the present disclosure begins at 404. At 408, a substrate having a diameter D is arranged in a pocket of a substrate support in a substrate processing chamber. For example, the substrate support corresponds to the substrate support 200 of FIG. 2A and is configured to function as an ESC. The substrate support comprises first and second D-shaped inner electrodes, a ring-shaped outer electrode, and a center portion passing between the first and second inner electrodes to connect to an inner diameter of the ring-shaped outer electrode. The inner diameter of the ring-shaped outer electrode is greater than the diameter D (e.g., 0.4 to 1.0 mm greater than D) of the substrate. At 412, the first and second inner electrodes are energized (e.g., connected to an ESC voltage) to clamp the substrate to the substrate support.

At 416, a deposition process is performed on the substrate. For example, a hard mask film is deposited on high-aspect ratio features of the substrate. The hard mask film is configured to pattern channel holes in slits between stacks of alternating films on the substrate. Depositing the hard mask film comprises generating plasma in the processing chamber. The method 400 ends at 420.

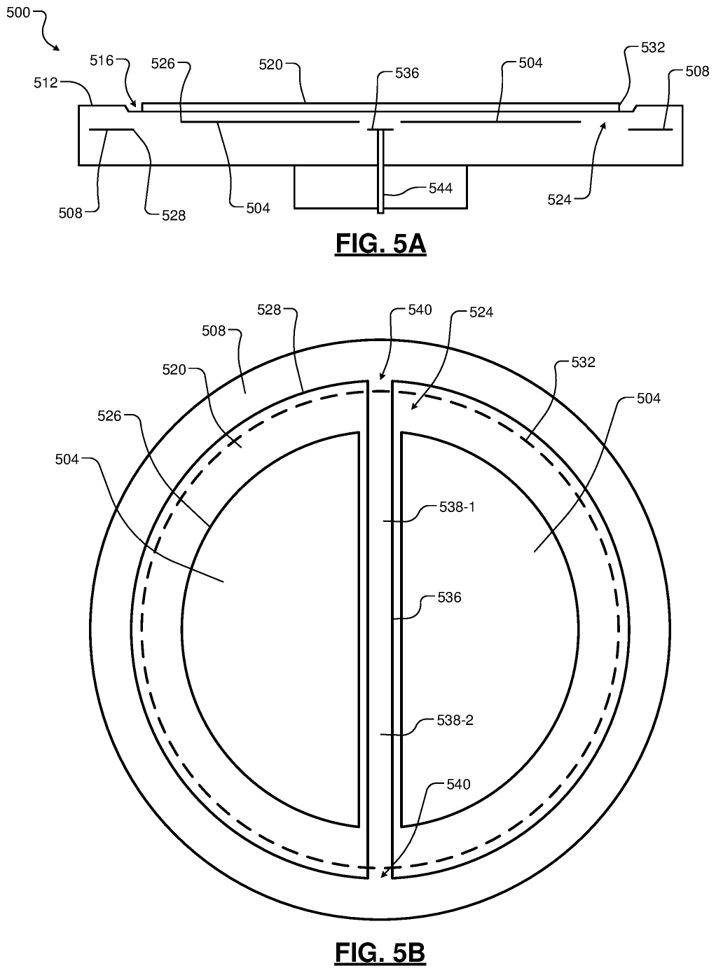

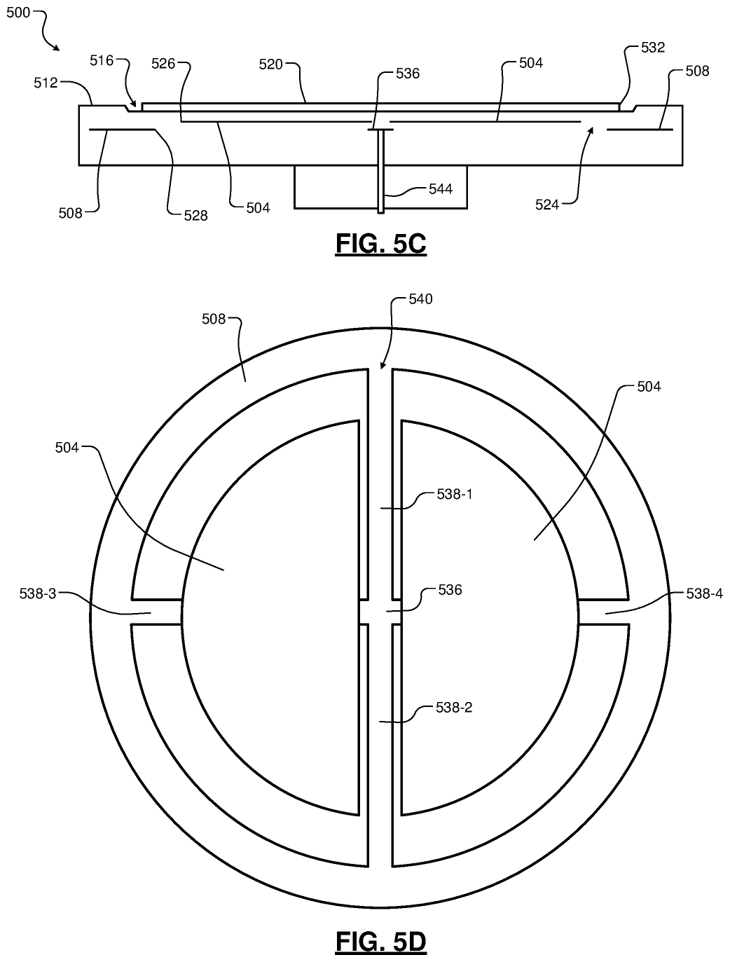

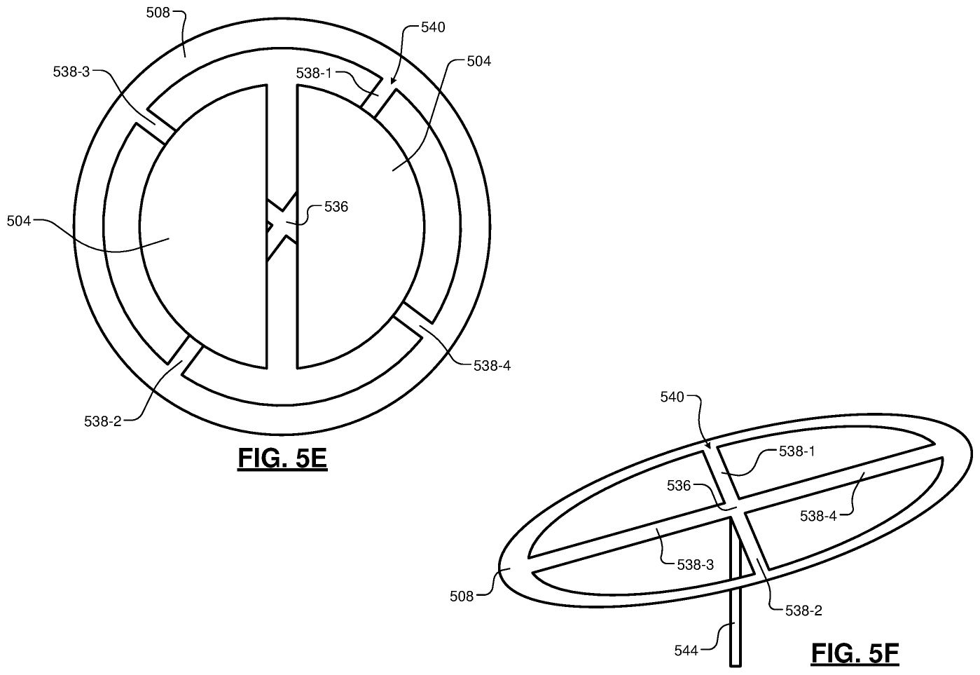

Referring now to FIGS. 5A, 5B, 5C, 5D, and 5E, another example substrate support 500 according to the present disclosure comprises two D-shaped (e.g., first and second) inner electrodes 504 and a ring-shaped outer electrode 508. In this example, the outer electrode 508 is arranged in a different plane than (i.e., is not coplanar with) the inner electrodes 504. As shown, the outer electrode 508 is arranged below the inner electrodes 504. A first (e.g., upper) surface 512 of the substrate support 500 comprises a pocket 516 configured to hold a substrate 520 arranged on the substrate support 500. A gap 524 is defined between the inner electrodes 504 (e.g., an outer diameter 526 defined by outer semi-circular edges of the inner electrodes 504) and an inner edge or diameter 528 of the outer electrode 508.

As shown in FIG. 5A, the gap 524 is located below an outer edge or diameter 532 of the substrate 520. Further, the inner diameter 528 of the outer electrode 508 is located radially outside of the outer diameter 532 of the substrate 520. In other words, the inner diameter 528 of the outer electrode 508 is greater than the outer diameter 532 of the substrate. The inner diameter 528 of the outer electrode 508 overlaps the pocket 516. As shown in another example in FIG. 5C, the inner diameter 528 of the outer electrode 508 overlaps the outer diameter 532 of the substrate 520.

As shown in FIG. 5B, a center strip or portion 536 comprising radial conductors 538-1 and 538-2 passes between the inner electrodes 504 to connect to opposite sides of the ring-shaped outer electrode 508. For example, the center portion 536 bisects a central opening of the outer electrode 508 to define two D-shaped openings. The inner electrodes 504 are arranged within the respective D-shaped openings. The ring-shaped outer electrode 508 and the center portion 536 may be formed in a single step (e.g., a single sintering step). In FIGS. 5A and 5B, intersections 540 between the center portion 536 and the outer electrode 508 are located radially outside of the outer diameter 532 of the substrate 520. Further, in FIGS. 5A and 5B, a width of the gap between the inner electrodes 504 is greater than a width of the center portion 536. Conversely, as shown in FIG. 5C, the width of the gap between the inner electrodes 504 is less than the width of the center portion 536. In other examples, the width of the gap between the inner electrodes 504 is the same as the width of the center portion 536.

As shown in FIGS. 5D and 5E, the center portion 536 may comprise more than two radial conductors (e.g., three, four, or more radial conductors) extending radially outward from a center point (e.g., corresponding of the center portion 536 toward the outer electrode 508. FIG. 5F shows an isometric view of the outer electrode 508 of FIGS. 5D and 5E. For example, the center portion 536 may comprise four of the radial conductors 538-1, 538-2, 538-3, and 538-4, referred to collectively as radial conductors 538. In this manner, the electrical connection between a conductive rod 544 (as shown in FIG. 5F) and the ring-shaped outer electrode 508 is distributed among a greater number (i.e., more than two) of the radial conductors 538 to reduce the impedance of the outer electrode 508. Further, localized heating caused by individual ones of the radial conductors 538 is reduced.

As shown in FIGS. 5B, the radial conductors 538 may be aligned (i.e., coaxial) with the gap between the inner electrodes 504. As shown in FIG. 5D, the radial conductors 538-1 and 538-2 are aligned with the gap between the inner electrodes 504 and the radial conductors 538-3 and 538-4 are not aligned with (i.e., are perpendicular or orthogonal to) the gap between the inner electrodes 504. Conversely, as shown in FIG. 5E, none of the radial conductors 538 are aligned with the gap between the inner electrodes 504.

In this manner (as described above in FIGS. 5A-5F), intersections between the center portion 536 and the ring-shaped outer electrode 508 are shifted below the inner electrodes 504 in a direction away from the first surface 512 of the substrate support 500. Accordingly, the occurrence of plasma hotspots above the substrate 520 is reduced or eliminated. Further, an impedance of the outer electrode 508 may be adjusted by locating the outer electrode 508 at different heights relative to the first surface 512 of the substrate support 500 and the inner electrodes 504.

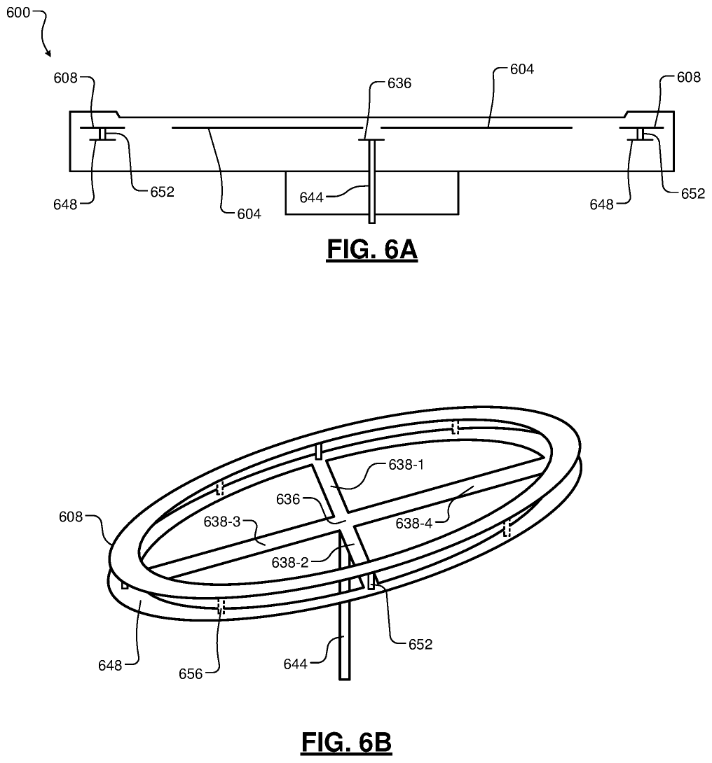

Referring now to FIGS. 6A and 6B, another example substrate support 600 according to the present disclosure comprises two D-shaped (e.g., first and second) inner electrodes 604 and a ring-shaped outer electrode 608. In this example, the outer electrode 608 is arranged in a same plane as (i.e., is coplanar with) the inner electrodes 604 (as shown in FIG. 6A) or in a different plane than (i.e., is not coplanar with) the inner electrodes 604. Conversely, a center portion 636 is arranged in a different plane than (i.e., is not coplanar with) the inner electrodes 604 and the outer electrode 608. As shown, the center portion 636 is arranged below the inner electrodes 604 and the outer electrode 608.

The center portion 636 comprises radial conductors 638-1, 638-2, 638-3, and 638-4 (referred to collectively as radial conductors 638). Although four of the radial conductors 638 are shown, the center portion 636 may comprise fewer (e.g., two) or more (e.g., five or more) of the radial conductors 638. The radial conductors 638 may have a width that is less than, the same as, or greater than a width of a gap between the D-shaped inner electrodes 604. The radial conductors 638 may be aligned (i.e., coaxial) with (e.g., as shown in FIG. 5D) or not aligned with (e.g., as shown in FIG. 5E) the gap between the D-shaped inner electrodes 604.

The radial conductors 638 are connected to a conductive rod 644 and a ring (e.g., a lower ring) 648 that surrounds and is coplanar with the radial conductors 638. The ring 648 may have a cross-sectional width, an inner diameter, and/or an outer diameter that is greater than, the same as, or lesser than a cross-sectional width, an inner diameter, and/or an outer diameter of the outer electrode 608. The ring 648 is connected to the ring-shaped outer electrode 608 via respective vertical portions (e.g., conductive posts, wiring, conductor-filled vias, etc.) 652. The vertical portions 652 may comprise a material that is the same as or different from the material of the radial conductors 638 and/or the outer electrode 608. A number of the vertical portions 652 (e.g., at least one) may be the same as or different from (e.g., greater than or less than) a number of the radial conductors 638. Further, although shown as being positioned at intersections of the radial conductors 638 and the ring 648, the vertical portions 652 may be positioned at other locations between the ring 648 and the outer electrode 608 (e.g., as shown in phantom at 656.

In this manner, the conductive rod 644 is electrically connected to the outer electrode 608. Further, since the electrical connection between the radial conductors 638 and the outer electrode 608 is shifted below the outer electrode 608 and distributed among multiple vertical portions 652, occurrences of plasma hotspots above the substrate support 600 are reduced or eliminated.

The foregoing description is merely illustrative in nature and is in no way intended to limit the disclosure, its application, or uses. The broad teachings of the disclosure can be implemented in a variety of forms. Therefore, while this disclosure describes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, such as “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, such as a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, such as the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may comprise chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may comprise a local network or the Internet. The remote computer may comprise a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may comprise a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A substrate support configured to support a substrate having a diameter D, the substrate support comprising:
a first inner electrode and a second inner electrode, wherein the first inner electrode and the second inner electrode are each D-shaped and define a first outer diameter that is less than D, and wherein the first inner electrode and the second inner electrode are configured to be connected to an electrostatic chuck (ESC) voltage to clamp the substrate to the substrate support during processing; and
an outer electrode that comprises (i) a ring-shaped outer portion that surrounds the first inner electrode and the second inner electrode and (ii) a center portion that passes between the first inner electrode and the second inner electrode to connect to opposite sides of an inner diameter of the ring-shaped outer portion,
wherein the inner diameter of the ring-shaped outer portion is greater than the diameter D such that the inner diameter of the ring-shaped outer portion and intersections between the center portion and the ring-shaped outer portion are located radially outside of the diameter D of the substrate.

2. The substrate support of claim 1, further comprising a gap defined between (i) the first outer diameter defined by the first inner electrode and the second inner electrode and (ii) the inner diameter of the ring-shaped outer portion.

3. The substrate support of claim 2, wherein the gap is located below and overlaps with an outer edge of the substrate.

4. The substrate support of claim 2, wherein the gap has a width between 2.2 and 7.5 mm.

5. The substrate support of claim 1, wherein the inner diameter of the ring-shaped outer portion is less than 1.0 mm greater than the diameter D of the substrate.

6. The substrate support of claim 1, wherein the inner diameter of the ring-shaped outer portion is between 300.4 and 305 mm.

7. The substrate support of claim 6, wherein the first outer diameter defined by the first inner electrode and the second inner electrode is between 290 and 296 mm.

8. The substrate support of claim 1, further comprising a pocket in a first surface of the substrate support, wherein the pocket is configured to hold the substrate.

9. The substrate support of claim 8, further comprising the substrate arranged in the pocket.

10. The substrate support of claim 8, wherein a diameter of the pocket is between 302 and 310 mm.

11. The substrate support of claim 8, wherein the inner diameter of the ring-shaped outer portion overlaps the pocket.

12. A substrate support configured to support a substrate, the substrate support comprising:
a first inner electrode and a second inner electrode, wherein the first inner electrode and the second inner electrode are each D-shaped, and wherein the first inner electrode and the second inner electrode are configured to be connected to an electrostatic chuck (ESC) voltage to clamp the substrate to the substrate support during processing; and
an outer electrode that comprises (i) a ring-shaped outer portion that surrounds the first inner electrode and the second inner electrode and (ii) a center portion that connects to opposite sides of an inner diameter of the ring-shaped outer portion,
wherein the outer electrode is not coplanar with the first inner electrode and the second inner electrode.

13. The substrate support of claim 12, wherein the outer electrode is positioned below the first inner electrode and the second inner electrode.

14. The substrate support of claim 12, wherein the center portion comprises a plurality of radial conductors that extend outward from a conductive rod to connect to the ring-shaped outer portion.

15. The substrate support of claim 14, wherein the plurality of radial conductors comprises two or more of the radial conductors.

16. The substrate support of claim 14, wherein the plurality of radial conductors comprises four or more of the radial conductors.

17. A substrate support configured to support a substrate, the substrate support comprising:
a first inner electrode and a second inner electrode, wherein the first inner electrode and the second inner electrode are each D-shaped, and wherein the first inner electrode and the second inner electrode are configured to be connected to an electrostatic chuck (ESC) voltage to clamp the substrate to the substrate support during processing; and
an outer electrode that comprises (i) a ring-shaped outer portion that surrounds the first inner electrode and the second inner electrode, (ii) a center portion positioned below the ring-shaped outer portion, (iii) a ring electrically connected to the center portion that surrounds and is coplanar with the center portion, and (iv) at least one vertical portion that electrically connects the ring to the ring-shaped outer portion.

18. The substrate support of claim 17, wherein the center portion comprises a plurality of radial conductors that extend outward from a conductive rod to connect to the ring.

19. The substrate support of claim 18, wherein the plurality of radial conductors comprises two or more of the radial conductors.

20. The substrate support of claim 18, wherein the plurality of radial conductors comprises four or more of the radial conductors.
